(19) United States
(12) Patent Application Publication
(10) Pub. No.: US 2022/0115321 A1
(43) Pub. Date: Apr. 14, 2022

(54) FUSE STRUCTURE AND FORMATION METHOD

(71) Applicant: CHANTGXIN MEMORY TECHNOLOGIES, INC., Hefei City (CN)

(72) Inventors: Mengmeng WANG, Hefei City (CN); HSIN-PIN HUANG, Hefei City (CN)

(21) Appl. No.: 17/480,332

(22) Filed: Sep. 21, 2021

Related U.S. Application Data
(63) Continuation of application No. PCT/CN2021/104792, filed on Jul. 6, 2021.

(30) Foreign Application Priority Data
Oct. 12, 2020 (CN) 202011086700.9

(51) Int. Cl. H01L 23/525

(52) U.S. Cl. CPC H01L 23/5256

(57) ABSTRACT

The present application discloses a fuse structure and a formation method. The fuse structure includes: a first dielectric layer, and at least two discrete first conductive plugs penetrating the first dielectric layer; a second conductive plug, the second conductive plug being electrically connected to the at least two first conductive plugs; a top metal layer, the top metal layer being electrically connected to the second conductive plug, and located on one side of the second conductive plug which is far from the first conductive plugs; and a second dielectric layer, the second dielectric layer being located on the top of the first dielectric layer, and the second conductive plug and the top metal layer being located in the second dielectric layer. The embodiments of the present application simplify the fuse structure, increasing the output efficiency of the fuse structure.

### CROSS-REFERENCE TO RELATED APPLICATIONS

The present application is a continuation application of International Patent Application No. PCT/CN2021/104792, filed on Jul. 6, 2021, which claims priority to Chinese Patent Application No. 202011086700.9, filed on Oct. 12, 2020 and entitled “FUSE STRUCTURE AND FORMATION METHOD”. International Patent Application No. PCT/CN2021/104792 and Chinese Patent Application No. 202011086700.9 are incorporated into the present application by reference in their entireties.

### TECHNICAL FIELD

The present application relates to the field of semiconductor manufacturing.

### BACKGROUND

A fuse is usually disposed in a semiconductor integrated circuit, and by blowing the fuse, the object of adjusting the functional parameters of the integrated circuit can be achieved. According to fuse blowing methods, fuses may be divided into electric fuses and laser fuses, among which the laser fuses are usually irradiated and then blown by using a laser beam with certain energy.

Complex fuse structures in a prior art lead to high process difficulty, and affect an output efficiency of products, and excessive energy is consumed during fuse blowing.

### SUMMARY

According to multiple embodiments, the first aspect of the embodiments of the present application provides a fuse structure and a formation method. The fuse structure includes: a first dielectric layer, and at least two discrete first conductive plugs penetrating the first dielectric layer; a second conductive plug, which electrically connected to the at least two first conductive plugs; a top metal layer, which electrically connected to the second conductive plug, and located on one side of the second conductive plug which is far from the first conductive plugs; and a second dielectric layer, which located on the top of the first dielectric layer, and wrapped around the second conductive plug and the top metal layer.

According to multiple embodiments, the second aspect of an embodiment of the present application further provides a formation method for a fuse structure, including: providing a first dielectric layer, and at least two discrete first conductive plugs penetrating the first dielectric layer being formed in the first dielectric layer; forming a second dielectric layer on the first dielectric layer; etching the second dielectric layer to form a via and a trench communicated with each other, the via being located between the trench and the first conductive plugs, and the width of the via being less than that of the trench; forming a second conductive plug filling the via, the second conductive plug being electrically connected to the at least two first conductive plugs; forming a top metal layer filling the trench, the top metal layer being electrically connected to the second conductive plug.

### BRIEF DESCRIPTION OF DRAWINGS

Exemplary descriptions will be made for one or more embodiments with reference to the pictures in the corresponding accompanying drawings without constituting a limitation to the embodiments. Elements with the same reference numerals in the accompanying drawings are represented as similar elements, and unless stated otherwise, the pictures in the accompanying drawings do not constitute a scale limitation.

FIG. 1 is a schematic diagram of a sectional structure of a fuse structure;

FIG. 2 is a schematic diagram of a sectional structure of a fuse structure according to a first embodiment of the present application;

FIGS. 3 to 5 are schematic structural diagrams corresponding to steps of a formation method for a fuse structure according to the first embodiment of the present application;

FIGS. 6 to 8 are schematic structural diagrams corresponding to steps of another formation method for a fuse structure according to the first embodiment of the present application;

FIG. 9 is a schematic sectional diagram of a fuse structure according to a second embodiment of the present application;

FIGS. 10 to 12 are schematic structural diagrams corresponding to steps of a formation method for a fuse structure according to the second embodiment of the present application; and

FIG. 13 is a schematic structural diagram corresponding to one step of another formation method for a fuse structure according to the second embodiment of the present application.

### DESCRIPTION OF EMBODIMENTS

Specific embodiments of a fuse structure and a formation method according to the present application will be described in detail hereinafter with reference to the accompanying drawings.

It can be known from the background art that fuse structures in the prior art need to be simplified.

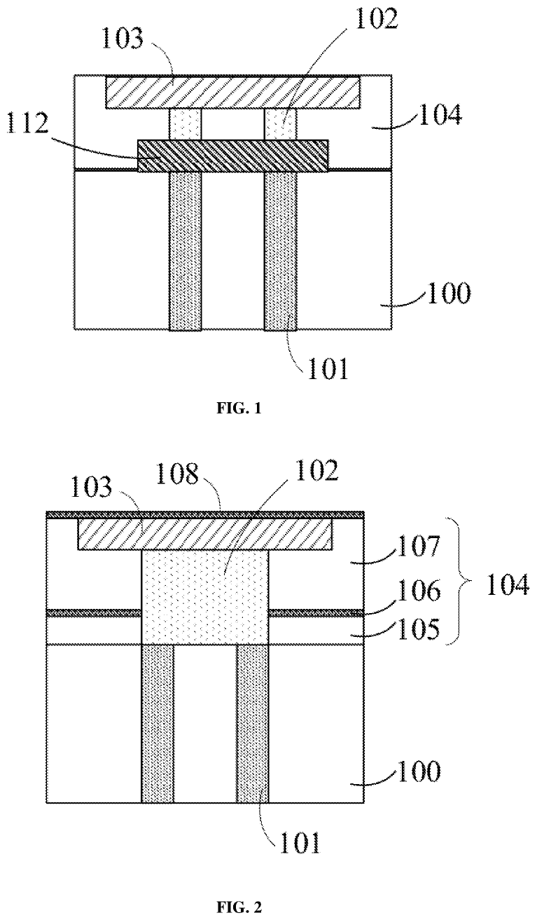

Referring to FIG. 1, a fuse structure includes: a first dielectric layer 100, first conductive plugs 101, a second dielectric layer 104, a bottom metal layer 112, second conductive plugs 102 and a top metal layer 103.

Since the second conductive plugs 102 are composed of a plurality of discrete structures between which a dielectric is present and the bottom metal layer 112 is present between the first conductive plug 101 and the second conductive plug 102, leading to the complex fuse structure, high process difficulty, and high production costs. Moreover, since the dielectric is present between the second conductive plugs 102, a lot of energy is consumed during the blowing of the fuse structure. Furthermore, the presence of the dielectric will lead to the incomplete blowing of the fuse structure during blowing, resulting in the problem that process parameters of an integrated circuit are difficult to control.

According to multiple embodiments, the first aspect of, the embodiments of the present application provide a fuse structure and a formation method. The fuse structure is simplified, which in turn decreases the difficulty of the process, thus reducing the production cost, increasing the output efficiency of products and helping solve the problem that excessive energy is consumed and a fuse structure cannot be completely blown during the blowing of the fuse structure.

In order to make the object, technical solution and advantages of the embodiments of the present application clearer, each embodiment of the present application will be set forth in detail hereinafter with reference to the accompanying drawings. However, those of ordinary skill in the art can understand that many technical details are put forward in each embodiment of the present application in order for readers to better understand the present application. However, even without these technical details and various changes and modifications based on the following embodiments, the technical solution which is required to be protected by the present application can still be implemented.

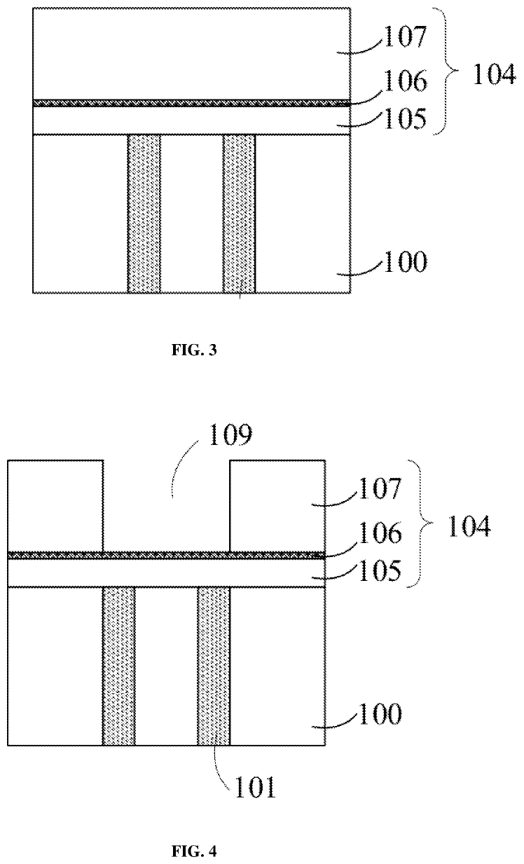

FIG. 2 is a schematic diagram of a sectional structure of a fuse structure according to a first embodiment of the present application.

Referring to FIG. 2, in the present embodiment, the fuse structure includes: a first dielectric layer 100, and at least two discrete first conductive plugs 101 penetrating the first dielectric layer 100; a second conductive plug 102, which electrically connected to the at least two first conductive plugs 101; a top metal layer 103, which electrically connected to the second conductive plug 102, and located on one side of the second conductive plug 102 which is far from the first conductive plugs 101; and a second dielectric layer 104, which located on the top of the first dielectric layer 100, and wrapped around the second conductive plug 102 and the top metal layer 103.

According to the fuse structure of the present embodiment, since the second conductive plug 102 is electrically connected to the at least two first conductive plugs 101, compared with the solution that the different second conductive plugs 102 are adopted to be connected to the corresponding first conductive plugs 101 respectively, this technical solution does not require the arrangement of dielectric between the second conductive plugs 102, and therefore, the fuse structure is simplified, which in turn decreases the difficulty of the process, thus reducing the production cost and increasing the output efficiency of products; and in addition, the problem that excessive energy is consumed and a fuse structure cannot be completely blown during the blowing of the fuse structure can also be solved, ensuring the accurate control of process parameters of the integrated circuit under the condition of low energy consumption.

The fuse structure according to the present embodiment will be described in detail hereinafter with reference to the accompanying drawings.

In the present embodiment, a material of the first dielectric layer 100 is silicon oxide, and a material of the first conductive plug 101 includes tungsten. In other embodiments, the material of the first dielectric layer 100 may also be other insulating materials, such as silicon nitride, silicon oxynitride, or the like, and the material of the first conductive plug 101 may also be other conductive materials, such as polycrystalline silicon, copper, or the like.

In addition, it should also be noted that the first dielectric layer 100 which is of a single-layered structure is taken as an example in the present embodiment. In other embodiments, the first dielectric layer 100 may also be of a laminated structure.

In the present embodiment, the material of the second conductive plug 102 is the same as that of the top metal layer 103, and may specifically be copper or tungsten. Thus, the second conductive plug 102 and the top metal layer 103 may be formed by deposition in one step, making the whole process simpler.

It should be noted that in other embodiments, the material of the second conductive plug 102 may also be different from that of the top metal layer 103.

In the present embodiment, a bottom surface of the second conductive plug 102 is in contact with top surfaces of the at least two first conductive plugs 101. Thus, in the fuse structure, the different first conductive plugs 101 are in contact with the same second conductive plug 102, the second conductive plug 102 is one-piece without a dielectric in it, and therefore, the single fuse structure is simple, decreasing the difficulty of the process. Moreover, since no dielectric with a high melting point is present in the single fuse structure, energy consumed during the blowing of the fuse structure can be reduced, and the difficulty of blowing the fuse structure can be decreased.

The second dielectric layer 104 wraps the second conductive plug 102 and the top metal layer 103, which may be located in the second dielectric layer 104.

The second dielectric layer 104 may include a first medium layer 105, a barrier layer 106 and a second medium layer 107 which are stacked in sequence; and the second conductive plug 102 at least penetrates the first medium layer 105 and the barrier layer 106.

The material of the first medium layer 105 is the same as that of the second medium layer 107, and may specifically be silicon oxide, silicon nitride, silicon oxynitride, silicon oxycarbonitride, or the like. The material of the barrier layer 106 is different from those of the first medium layer 105 and the second medium layer 107, and, for example, may be silicon nitride. The functions of the barrier layer 106 include: stopping etching in the process steps of producing the fuse structure and decreasing the difficulty of the etching process.

In the present embodiment, the second conductive plug 102 located between the first dielectric layer 100 and the second medium layer 107 has a first thickness, the top metal layer 103 has a second thickness, and the first thickness may be equal to the second thickness. It can be understood that the relationship between the first thickness and the second thickness is related to a production process for the fuse structure. That is, the second conductive plug 102 and the top metal layer 103 are produced by employing dual damascene processes, which include a “via first trench last” method and a “via last trench first” method.

It should be noted that in other embodiments, the second dielectric layer 104 may also be of a single-layered structure.

In the present embodiment, the fuse structure may further include a protective layer 108, which is located on one side of the top metal layer 103 that is far from the second conductive plug 102. The protective layer 108 can provide protection for the top metal layer 103, e.g., protecting the top metal layer 103 from being etched or damaged by the subsequent process. The protective layer 108 may be of a single-layered structure, or may be a multi-layered structure made of a variety of materials. For example, the protective layer 108 is of a single-layered structure made of silicon nitride, or the protective layer 108 is of a multi-layered structure with the surface made of silicon nitride.

The fuse structure according to the present embodiment is simplified, which in turn decreases the difficulty of the process, thus reducing the production cost and increasing the output efficiency of products; and in addition, the problem that excessive energy is consumed and a fuse structure cannot be completely blown during the blowing of the fuse structure can also be solved, ensuring the accurate control of process parameters of the integrated circuit under the condition of low energy consumption.

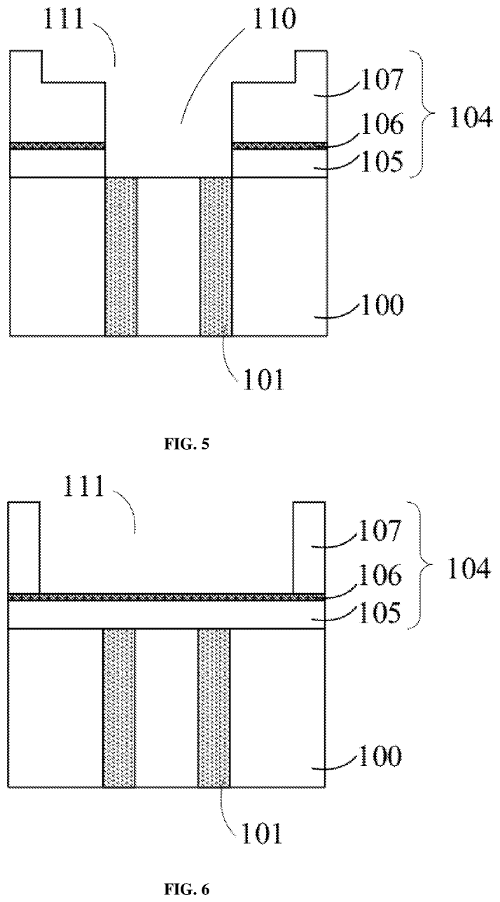

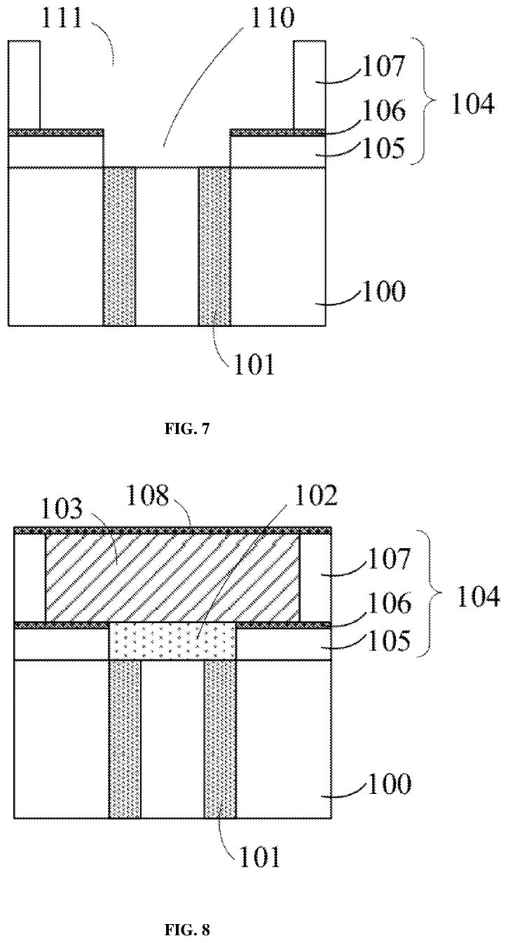

Formation methods for the fuse structure according to the present embodiment will be described hereinafter with reference to the accompanying drawings. FIGS. 3 to 5 are schematic structural diagrams corresponding to steps of a formation method for a fuse structure according to the first embodiment of the present application; and FIGS. 6 to 8 are schematic structural diagrams corresponding to steps of another formation method for a fuse structure according to the first embodiment of the present application.

Referring to FIG. 3, the formation method includes: providing a first dielectric layer 100, at least two discrete first conductive plugs 101 penetrating the first dielectric layer 100 being formed in the first dielectric layer 100.

Continuing to refer to FIG. 3, the formation method further includes: forming a second dielectric layer 104 on the first dielectric layer 100.

Forming a second dielectric layer 104 on the first dielectric layer 100 includes: sequentially stacking a first medium layer 105, a barrier layer 106 and a second medium layer 107.

Subsequent process steps include: etching the second dielectric layer 104 to form a via 110 and a trench 111 communicated with each other, the via 110 being located between the trench 111 and the first conductive plugs 101, and the width of the via 110 being less than that of the trench 111. The formation of the via 110 and the trench 111 in a “via 110 first trench 111 last” manner will be described as an example hereinafter.

Referring to FIG. 4, the formation method further includes: etching the second medium layer 107 until the barrier layer 106 is exposed, so that an initial via 109 is formed.

Referring to FIG. 5, the formation method further includes: etching away a partial thickness of second medium layer 107 located around the initial via 109, and etching the barrier layer 106 and the first medium layer 105 exposed out of the initial via 109 until the first conductive plugs 101 are exposed, so that the via 110 and the trench 111 are formed.

It should be noted that in the present embodiment, the via 110 and the trench 111 are formed in the “via 110 first trench 111 last” manner. In other embodiments, as shown in FIG. 6 and FIG. 7, the via 110 and the trench 111 may also be formed in a “trench 111 first via 110 last” manner, which is specifically as follows.

Referring to FIG. 6, forming a second dielectric layer 104 on the first dielectric layer 100 includes: sequentially stacking the first medium layer 105, the barrier layer 106 and the second medium layer 107; and etching the second medium layer 107 until the barrier layer 106 is exposed, so that the trench 111 is formed.

Referring to FIG. 7, the barrier layer 106 in part of the region at the bottom of the trench 111 and the first medium layer 105 are etched until the first conductive plugs 101 are exposed, so that the via 110 and the trench 111 are formed.

Referring to FIG. 2 or FIG. 8, the formation method further includes: forming a second conductive plug 102 filling the via 110, the second conductive plug 102 being electrically connected to the at least two first conductive plugs 101; forming a top metal layer 103 filling the trench 111, the top metal layer 103 being electrically connected to the second conductive plug 102.

Thus, by employing the dual damascene processes, while the fuse structure is formed, it is ensured that an overlay accuracy of the fuse structure is high; since the second conductive plug 102 is electrically connected to the at least two first conductive plugs 101, compared with the solution that the different second conductive plugs 102 are adopted to be connected to the corresponding first conductive plugs 101 respectively, this technical solution does not require the arrangement of dielectric between the second conductive plugs 102, and therefore, the fuse structure is simplified, which in turn decreases the difficulty of the process, thus reducing the production cost and increasing the output efficiency of products; and in addition, the problem that excessive energy is consumed and a fuse structure cannot be completely blown during the blowing of the fuse structure is solved, ensuring the accurate control of process parameters of an integrated circuit under the condition of low energy consumption.

Continuing to refer to FIG. 2 or FIG. 8, after the top metal layer 103 is formed, the formation method further includes: forming a protective layer 108 on the surface of the top metal layer 103. Thus, the formed fuse structure can be protected from being etched or damaged by the subsequent process.

The first embodiment of the present application provides a fuse structure and the formation method. The second conductive plug 102 is electrically connected to the at least two first conductive plugs 101. Compared with the solution that the different second conductive plugs 102 are adopted to be connected to the corresponding first conductive plugs 101 respectively, this technical solution does not require the arrangement of dielectric between the second conductive plugs 102, and therefore, the fuse structure is simplified, which in turn decreases the difficulty of the process, thus reducing the production cost and increasing the output efficiency of products; and in addition, the problem that excessive energy is consumed and a fuse structure cannot be completely blown during the blowing of the fuse structure is solved, ensuring the accurate control of process parameters of an integrated circuit under the condition of low energy consumption.

A second embodiment of the present application further provides a fuse structure and a formation method thereof. The second embodiment is nearly the same as the aforementioned embodiment, but the main difference is in that the fuse structure further includes a bottom metal layer 212.

The fuse structure and the formation method according to the second embodiment of the present application will be described in detail hereinafter with reference to the accompanying drawings. For the parts which are the same as or correspond to those in the aforementioned embodiment, please refer to the description of the aforementioned embodiment, so they will not be repeated hereinafter.

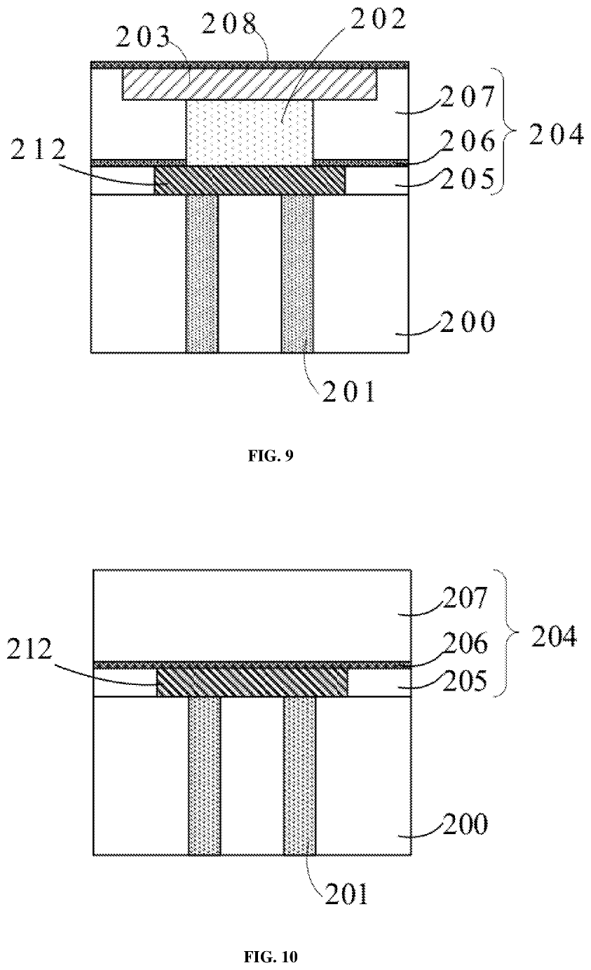

FIG. 9 is a schematic diagram of a sectional structure of the fuse structure according to the second embodiment of the present application.

Referring to FIG. 9, in the present embodiment, the fuse structure includes: a first dielectric layer 200, first conductive plugs 201, a second conductive plug 202, a top metal layer 203 and a second dielectric layer 204. The fuse structure further includes a bottom metal layer 212, which is located between the first conductive plugs 201 and the second conductive plug 202 and electrically connected to the first conductive plugs 201 and the second conductive plug 202 respectively.

According to the fuse structure of the present embodiment, since the second conductive plug 202 is electrically connected to the at least two first conductive plugs 201, compared with the solution that the different second conductive plugs 202 are adopted to be connected to the corresponding first conductive plugs 201 respectively, this technical solution does not require the arrangement of dielectric between the second conductive plugs 202. Therefore, in the process of forming the fuse structure, the process steps are simplified, the difficulty of the process is decreased, the output efficiency of products is increased, and the fuse structure can be more completely blown, so that process parameters of an integrated circuit can be accurately controlled.

The fuse structure according to the present embodiment will be described in detail hereinafter with reference to the accompanying drawings.

The second dielectric layer 204 includes a first medium layer 205, a barrier layer 206 and a second medium layer 207 which are sequentially stacked; and the barrier layer 206 is located on part of the top surface of the bottom metal layer 212. The material of the first medium layer 205 is the same as that of the second medium layer 207, and may specifically be silicon oxide, silicon nitride, silicon oxynitride, silicon oxycarbonitride, or the like. The material of the barrier layer 206 is different from those of the first medium layer 205 and the second medium layer 207, and, for example, may be silicon nitride. The functions of the barrier layer 206 include: stopping etching in the process steps of producing the fuse structure and decreasing the difficulty of the etching process.

In the present embodiment, the materials of the bottom metal layer 212, the second conductive plug 202 and the top metal layer 203 are the same, and may specifically be copper or tungsten. Thus, the second conductive plug 202 and the top metal layer 203 may be formed by deposition in one step, making the whole process simpler.

In a direction parallel to the arrangement direction of the discrete first conductive plugs 201, the width of the second conductive plug 202 is less than that of the bottom metal layer 212.

The fuse structure according to the present embodiment is simplified, which in turn decreases the difficulty of the process, thus reducing the production cost and increasing the output efficiency of products; and in addition, the problem that excessive energy is consumed and a fuse structure cannot be completely blown during the blowing of the fuse structure can also be solved, ensuring the accurate control of process parameters of an integrated circuit under the condition of low energy consumption.

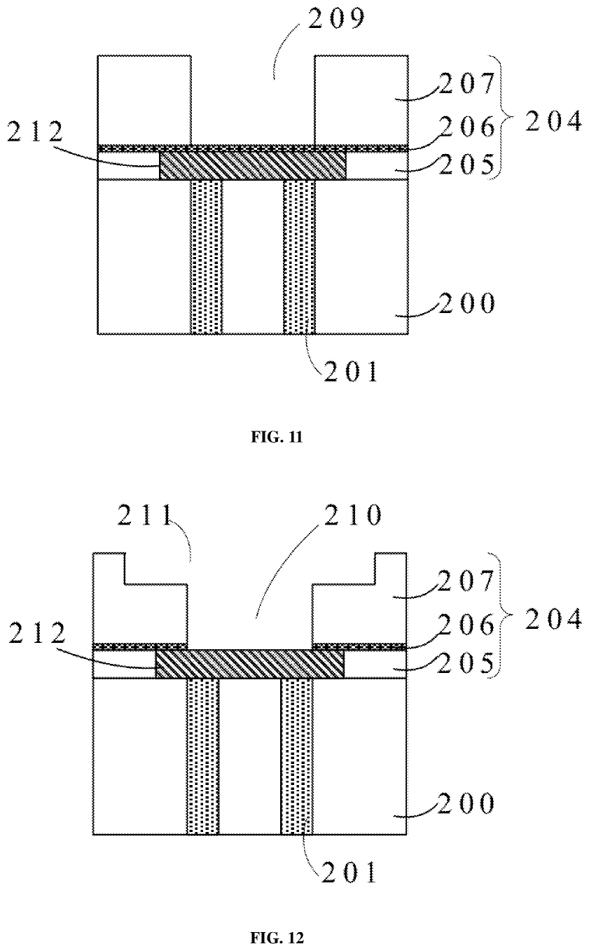

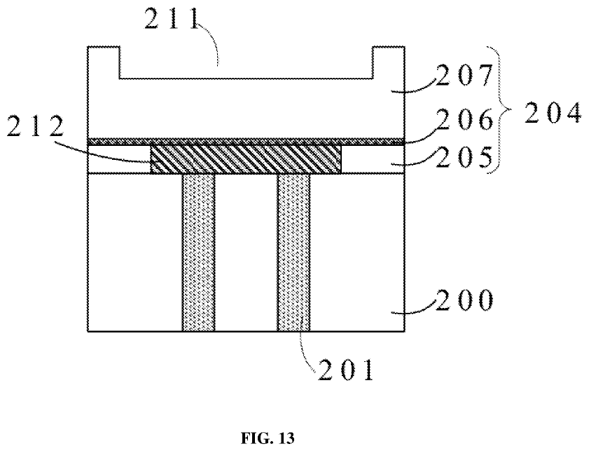

Formation methods for the fuse structure according to the present embodiment will be described hereinafter with reference to the accompanying drawings. FIGS. 10 to 12 are schematic structural diagrams corresponding to steps of the formation method for a fuse structure according to the second embodiment of the present application; and FIG. 13 is a schematic structural diagram corresponding to one step of another formation method for a fuse structure according to the second embodiment of the present application.

Referring to FIG. 10, the formation method includes: providing a first dielectric layer 200, first conductive plugs 201 and a second dielectric layer 204.

The formed second dielectric layer 204 includes a first medium layer 205, a barrier layer 206 and a second medium layer 207 which are sequentially stacked.

Continuing to refer to FIG. 10, prior to the formation of the barrier layer 206, the formation method further includes: forming a bottom metal layer 212 penetrating the first medium layer 205, the bottom metal layer 212 being in contact with the at least two first conductive plugs 201, and the bottom metal layer 212 being exposed out of a via 210.

Subsequent process steps include: etching the second dielectric layer 204 to form the via 210 and a trench 211 communicated with each other, the via 210 being located between the trench 211 and the first conductive plugs 201, and the width of the via 210 being less than that of the trench 211. The formation of the via 210 and the trench 211 in a “via 210 first trench 211 last” manner will be described as an example hereinafter.

Referring to FIG. 11, the formation method further includes: etching the second medium layer 207 until the barrier layer 206 is exposed, so that an initial via 209 is formed.

Referring to FIG. 12, the formation method further includes: etching away a partial thickness of the second medium layer 207 located around the initial via 209, and etching the barrier layer 206 at the bottom of the initial via 209 to expose the bottom metal layer 212, so that the trench 211 and the via 210 are formed.

It should be noted that in the present embodiment, the via 210 and the trench 211 are formed in the “via 210 first trench 211 last” manner. In other embodiments, as shown in FIG. 12 and FIG. 13, the via 210 and the trench 211 may also be formed in a “trench 211 first via 210 last” manner, which is specifically as follows:

referring to FIG. 13, etching a partial thickness of second medium layer 207 to forma trench 211;

referring to FIG. 12, etching the second medium layer 207 in part of the region at the bottom of the trench 211, and etching the barrier layer 206 until the bottom metal layer 212 is exposed, so that the trench 211 and the via 210 are formed.

Referring to FIG. 9, the formation method further includes: after the via 210 and the trench 211 are formed, filling the via 210 to form a second conductive plug 202, and filling the trench 211 to form a top metal layer 203.

Thus, by employing the dual damascene processes, while the fuse structure is formed, it is ensured that the overlay accuracy of the fuse structure is high; since the second conductive plug 202 is electrically connected to the at least two first conductive plugs 201, compared with the solution that the different second conductive plugs 202 are adopted to be connected to the corresponding first conductive plugs 201 respectively, this technical solution does not require the arrangement of dielectric between the second conductive plugs 202. Therefore, in the process of forming the fuse structure, the process steps are simplified, the difficulty of the process is decreased, the output efficiency of products is increased, and the fuse structure can be more completely blown, so that process parameters of an integrated circuit can be accurately controlled.

Continuing to refer to FIG. 9, after the top metal layer 203 is formed, the formation method further includes: forming a protective layer 208 on the surface of the top metal layer 203. Thus, the formed fuse structure can be protected from being etched or damaged by the subsequent process.

The fuse structure and the formation method according to the second embodiment of the present application have the following advantages: since the second conductive plug 202 is electrically connected to the at least two first conductive plugs 201, compared with the solution that the different second conductive plugs 202 are adopted to be connected to the corresponding first conductive plugs 201 respectively, this technical solution does not require the arrangement of dielectric between the second conductive plugs 202; therefore, in the process of forming the fuse structure, the process steps are simplified, the difficulty of the process is decreased, the output efficiency of products is increased, and the fuse structure can be more completely blown, so that process parameters of an integrated circuit can be accurately controlled.

Those of ordinary skill in the art should understand that the aforementioned embodiments are the specific embodiments implementing the present application. However, in practical application, various changes can be made to the embodiments in terms of forms and details without departing from the spirit and scope of the present application. Any person skilled in the art can make respective alterations and modifications without departing from the spirit and scope of the present application, so the protection scope of the present application should be subject to the scope defined by the claims.

What is claimed is:

1. A fuse structure, comprising:
a first dielectric layer, and at least two discrete first conductive plugs penetrating the first dielectric layer;
a second conductive plug, which is electrically connected to the at least two first conductive plugs;
a top metal layer, which is electrically connected to the second conductive plug, and located on one side of the second conductive plug which is far from the first conductive plugs; and
a second dielectric layer, which is located on top of the first dielectric layer, and wrapped around the second conductive plug and the top metal layer.

2. The fuse structure according to claim 1, wherein a bottom surface of the second conductive plug is in contact with top surfaces of the at least two first conductive plugs.

3. The fuse structure according to claim 2, wherein the second dielectric layer comprises a first medium layer, a barrier layer and a second medium layer which are sequentially stacked; and
the second conductive plug at least penetrates the first medium layer and the barrier layer.

4. The fuse structure according to claim 1, further comprising:
a bottom metal layer, which is located between the first conductive plugs and the second conductive plug, and electrically connected to the first conductive plugs and the second conductive plug respectively.

5. The fuse structure according to claim 4, wherein the second dielectric layer comprises:
a first medium layer, a barrier layer and a second medium layer which are sequentially stacked; and
the barrier layer is located on part of a top surface of the bottom metal layer.

6. The fuse structure according to claim 4, wherein in a direction parallel to an arrangement direction of the discrete first conductive plugs, a width of the second conductive plug is less than that of the bottom metal layer.

7. The fuse structure according to claim 1, further comprising:
a protective layer, located on one side of the top metal layer that is far from the second conductive plug.

8. A formation method for a fuse structure, comprising:
providing a first dielectric layer, at least two discrete first conductive plugs penetrating the first dielectric layer being formed in the first dielectric layer;
forming a second dielectric layer on the first dielectric layer;
etching the second dielectric layer to form a via and a trench communicated with each other, the via being located between the trench and the first conductive plugs, and a width of the via being less than that of the trench;
forming a second conductive plug filling the via, the second conductive plug being electrically connected to the at least two first conductive plugs; and
forming a top metal layer filling the trench, the top metal layer being electrically connected to the second conductive plug.

9. The formation method for a fuse structure according to claim 8, wherein the second dielectric layer comprises:
a first medium layer, a barrier layer and a second medium layer which are sequentially stacked; and
prior to the formation of the barrier layer, the formation method further comprises: forming a bottom metal layer penetrating the first medium layer, the bottom metal layer being in contact with the at least two first conductive plugs, and the bottom metal layer being exposed out of the via.

10. The formation method for a fuse structure according to claim 9, wherein the process steps for forming the via and the trench comprise:
etching the second medium layer until the barrier layer is exposed, so that an initial via is formed; and
etching away a partial thickness of second medium layer located around the initial via, and etching the barrier layer at a bottom of the initial via to expose the bottom metal layer, so that the trench and the via are formed.

11. The formation method for a fuse structure according to claim 9, wherein the process steps for forming the via and the trench comprise:
etching a partial thickness of second medium layer to form the trench; and
etching the second medium layer in part of a region at a bottom of the trench, and etching the barrier layer until the bottom metal layer is exposed, so that the trench and the via are formed.

12. The formation method for a fuse structure according to claim 8, wherein the forming a second dielectric layer on the first dielectric layer comprises:
sequentially stacking a first medium layer, a barrier layer and a second medium layer; and
the process steps for forming the via and the trench comprise: etching the second medium layer until the barrier layer is exposed, so that an initial via is formed; and
etching away a partial thickness of second medium layer located around the initial via, and etching the barrier layer and the first medium layer exposed out of the initial via until the first conductive plugs are exposed, so that the via and the trench are formed.

13. The formation method for a fuse structure according to claim 8, wherein the forming a second dielectric layer on the first dielectric layer comprises:
sequentially stacking a first medium layer, a barrier layer and a second medium layer; and
the process steps for forming the via and the trench comprise: etching the second medium layer until the barrier layer is exposed, so that the trench is formed; and
etching the barrier layer and the first medium layer in part of a region at a bottom of the trench until the first conductive plugs are exposed, so that the via and the trench are formed.

14. The formation method for a fuse structure according to claim 8, wherein after the top metal layer is formed, the formation method further comprises: forming a protective layer on a surface of the top metal layer.
